(19) United States
(12) Patent Application Publication
(10) Pub. No.: US 2014/0246092 A1
(43) Pub. Date: Sep. 4, 2014

(54) SILICON SUBSTRATE AND MANUFACTURING METHOD THEREOF

(71) Applicant: Panasonic Corporation, Osaka (JP)

(72) Inventors: KOUJI ARAI, Nara (JP); NAOSHI YAMAGUCHI, Osaka (JP); HIROSHI TANABE, Nara (JP)

(73) Assignee: Panasonic Corporation, Osaka (JP)

(21) Appl. No.: 14/191,436

(22) Filed: Feb. 27, 2014

(30) Foreign Application Priority Data
Mar. 1, 2013 (JP) 2013-040470

(51) Int. Cl. H01L 31/0236; H01L 31/0352

(52) U.S. Cl. CPC H01L 31/02366; H01L 31/0352
USPC 136/261; 438/706

(57) ABSTRACT

A silicon substrate having a new shape on the opposite surface side of textures can be manufactured at low costs by performing high-quality washing to the silicon substrate with a substrate plane orientation (100) having a texture structure by using a gas etching method, thereby improving use efficiency of light. A silicon substrate is provided having the substrate plane orientation (100) with textures, in which fine rectangular-shaped unevenness is formed in a ripple shape on the opposite side surface of the texture-formed surface, and the depth of concave portions therein is 10 to 200 nm.

### BACKGROUND OF THE INVENTION

1. Field of the Invention

The present invention relates to a silicon substrate having a surface on which fine rectangular-shaped unevenness is formed in a ripple shape and a manufacturing method thereof.

2. Description of Related Art

A solar cell is a device converting light energy such as sunlight incident on the surface of the solar cell into electrical energy. In order to improve the conversion efficiency to the electrical energy, various attempts have been made from the past. As one of the attempts, there is a technique that reduces reflection of light incident on the surface of a substrate, in which the conversion efficiency to the electrical energy can be increased by reducing the reflection of incident light.

Accordingly, a silicon solar cell (photoelectric conversion device) and the like have a rough shape called textures on a light receiving surface of a silicon substrate to thereby suppress reflection of incident light and prevent light taken into the silicon substrate from leaking to the outside.

The formation of textures on the surface of the silicon substrate is generally performed by a wet process using an alkaline (KOH) solution as an etchant (refer to JP-A-2006-344765 (Patent Document 1). After forming textures by the wet process, a washing process by using hydrogen fluoride, a heat treatment process and the like are necessary as post processes.

On the other hand, methods of forming textures on the surface of the silicon substrate by a. dry process have been also proposed. For example, there are proposed (1) a method of using a technique called a reactive ion etching by using plasma and (2) a method of etching the surface of the silicon substrate by introducing any of gases of ClF₃, XeF₂, BrF₃ and BrF₅ into a reaction chamber under atmospheric pressure in which the silicon substrate exists (refer to JP-A-2003-197940 (Patent Document 2) and JP-A-10-313123 (Patent Document 3).

Moreover, in order to take the sunlight into the silicon substrate more efficiently, there is proposed a method in which electrodes and junctions between the electrodes and wiring which have been on the light receiving surface side for the sunlight are arranged on the opposite side surface of the light receiving surface, thereby improving conversion efficiency of the solar cell (refer to JP-A-2008-186927 (Patent Document 4)).

In every case, the substrate is washed by a chemical liquid such as hydrofluoric acid and pure water after forming textures.

### SUMMARY OF THE INVENTION

In recent years, further improvement in use efficiency of light which has reached the silicon substrate and cost reduction in washing including the formation of textures are inevitable for aiming to reduce costs for the solar cell and for increasing the conversion efficiency at the time of converting light into electricity.

As described above, in the case where the textures are formed by the wet process, a great deal of the chemical liquid and pure water is used and a great deal of pure water is used for the washing after farming textures, therefore, costs for the chemical liquid and wastewater treatment are high. Accordingly, it may be disadvantageous in costs to manufacture the substrate for the solar cell.

The methods of forming textures on the surface of the silicon substrate by the dry process have been also proposed as described above. However, in these methods, it may be difficult to obtain a desired texture structure as excessive heat generation reaction may occur between a reactive gas and the silicon substrate. Moreover, when the silicon substrate is exposed to the gas in a plasma state at the time of etching, it may be difficult to sufficiently secure conversion efficiency from light to electricity as plasma damage may occur on the surface of the silicon substrate.

Accordingly, it is necessary to add a process for restoring the silicon substrate from the damage and the washing of the substrate is performed by the wet process, which increase the costs tor the chemical liquid as well as tor the chemical liquid and wastewater treatment.

As described above, there has been also proposed the structure in which the electrodes are provided on the opposite side of the light incident surface to thereby eliminate portions blocking light and to increase use efficiency of light. When such a back contact structure is formed, it is difficult to form a desired wiring width at the time of forming the wiring in the case where unevenness of 1 μm or more is formed on the electrode-formed surface. Accordingly, a silicon dioxide film or a silicon nitride film is previously formed on a wiring-formed surface as a texture etching mask, then, textures are formed by the wet process and the texture mask is removed to planarize the back surface.

Therefore, not only costs for the chemical liquid as well as the chemical liquid and wastewater treatment due to the execution of the wet process are increased but also incident light goes through the back surface as the back surface is planarized, therefore, light is not utilized efficiently.

The texture structure on the light incident surface in related art is not sufficient by itself for increasing the efficiency of the solar cell, and it is essential to create the silicon substrate (particularly a widely-available (100) substrate) which can utilize light more effectively at lower costs.

Accordingly, an object of the present invention is to manufacture and provide a silicon substrate at low costs, which has a new shape on the opposite surface side of the textures by performing high-quality washing to the silicon substrate having a substrate plane orientation (100) with the texture structure by a gas etching method for improving use efficiency of light. Another object of the present invention is to provide a solar cell including the silicon substrate.

That is, the present invention relates to the silicon substrate and the manufacturing method thereof which will be described below.
(1) silicon substrate having a substrate plane orientation (100) including textures on one surface for receiving light, and fine rectangular-shaped unevenness in a ripple shape on the other surface which is the opposite side of the surface on which the textures are formed, in which the depth of concave portions is 10 to 200 nm.
(2) The silicon substrate in the above (1), in which the depth of the unevenness formed in the ripple shape ranges from 10 nm to 100 nm.
(3) The silicon substrate in the above (1) or (2), in which the density of the unevenness on the other surface is 10 to 100000 pieces/100 μm².
(4) The silicon substrate in any of the above (1) to (3), in which the absorptivity of incident light (wavelength 0.5 to 10 μm) onto the silicon substrate is 30% or more.
(5) A manufacturing method of a silicon substrate including the steps of preparing a silicon substrate having a substrate plane orientation (100), and spraying an etching gas to the surface of the silicon substrate, in which the etching gas includes one or more gases selected from the group consisting of ClF₃, XeF₂, BrF₃, BrF₅ and NF₃ as well as a gas containing oxygen atoms in molecules, which processes the surface of the silicon substrate by non-plasma.
(6) The manufacturing method of the silicon substrate in the above (5), in which the etching gas further includes an inert gas.
(7) The manufacturing method of the silicon substrate in the above (5) or (6), in which, in the etching gas, the concentration of one or more gases selected from the group consisting of ClF₃, XeF₂, BrF₃, BrF₅ and NF₃ with respect to the total flow rate during etching processing is 1 to 10%.
(8) The manufacturing method of the silicon substrate in any of the above (5) to (7), in which, in the etching gas, the concentration of the gas containing oxygen atoms in molecules with respect to the total flow rate during etching processing is 4 to 40%
(9) The manufacturing method of the silicon substrate in any of the above (5) to (8), in which, in the etching gas, the ratio between the one or more gases selected from the group consisting of ClF₃, XeF₂, BrF₃, BrF₅ and NF₃ and the gas containing oxygen atoms in molecules is 1:10 to 1:3.
(10) The manufacturing method of the silicon substrate in any of the above (5) to (9), in which the temperature of the silicon substrate is maintained to 130° C. or less.
(11) The manufacturing method of the silicon substrate in the above (5), in which the etching of the silicon substrate is performed under a reduced pressure condition.

(12) The manufacturing method of the silicon substrate in any of the above (5) to (11), further including the step of washing the silicon substrate, in which the washing of the silicon substrate is performed by using fluonitric acid.

(13) The manufacturing method of the silicon substrate in any of the above (5) to (11), further including the step of washing the silicon substrate, in which the washing of the silicon substrate is performed by using sodium hydroxide.

As the silicon substrate according to the present invention has the texture-formed surface in addition to the surface on which fine rectangular-shaped unevenness is formed in the ripple shape, and the reflectance thereof is low. Accordingly, as the texture-formed surface is used as the light receiving surface, light is further confined in the silicon substrate by the fine rectangular-shaped unevenness in the ripple shape, and the substrate is used as the silicon substrate for the solar cell more suitably as compared with the substrate with the structure in which only textures are formed.

Moreover, as the fine rectangular-shaped unevenness in the ripple shape according to the present invention has a minute structure, the silicon substrate can be formed to be thin, which can increase material efficiency of the silicon substrate as well as can increase the degree of freedom in device design.

### BRIEF DESCRIPTION OF THE DRAWINGS

FIG. 1 is an electron micrograph showing an example of a surface on which fine rectangular-shaped unevenness is formed in a ripple shape in a silicon substrate according to the present invention;

FIG. 2 is a view showing an example in which a desired surface having fine rectangular-shaped unevenness in a ripple shape has not been obtained though dry-etching was performed to the silicon substrate;

FIGS. 3A and 3B are views showing an outline of a manufacturing device of manufacturing the silicon substrate used in examples; and

FIG. 4A is a graph showing the reflectance in a substrate (reference example) on which a fine uneven surface is not formed on an opposite surface of a surface on which textures are formed in a silicon substrate with a substrate plane orientation (100), and a substrate (Example 1) having the fine uneven surface on the opposite surface of the silicon substrate, and FIG. 4B is a graph showing the absorptivity in the substrate (reference example) on which the fine uneven surface is not formed on the opposite surface of the surface on which textures are formed in the silicon substrate with a substrate plane orientation (100) and the substrate (Example 1) having the fine uneven surface on the opposite surface of the silicon substrate.

### DESCRIPTION OF PREFERRED EMBODIMENTS

1. A silicon substrate having a surface on which textures are formed and a surface on which fine rectangular-shaped unevenness is formed in a ripple shape:

In a silicon substrate according to the present invention, textures and fine rectangular-shaped unevenness in the ripple shape are formed on substrate surfaces. The substrate surface on which textures are formed is called a texture-formed surface and a surface on which fine rectangular-shaped unevenness is formed in the ripple shape is called a fine uneven surface.

The silicon substrate is preferably made of single-crystal silicon. In this case, p-type doped silicon, n-type doped silicon, or intrinsic silicon can be used. In any case, the silicon substrate is a silicon substrate having a substrate plane orientation (100).

One of features of the silicon substrate having the fine uneven surface according to the present invention is that the silicon substrate has the plane orientation (100). In the related-art washing of the silicon substrate having the substrate plane orientation (100) by a wet process, organic constituents and contamination on the surface can be removed, but, it is difficult to form fine rectangular-shaped unevenness in the ripple shape on the silicon substrate.

The fine uneven surface stands for a surface with low reflection of light. The surface with low reflection is a surface in which the reflectance is approximately 20% or less when the reflectance on a mirror surface with respect to light having wavelengths of 0.5 to 1.0 μm is 100%. The reflectance of the surface is more preferably 10% or less, and is practically 0%.

The absorptivity (wavelength range 0.5 to 1.0 μm) of the silicon substrate having the fine rectangular-shaped uneven surface according to the present invention is preferably 80% or more, more preferably 85% or more. The absorptivity can be measured by an integrating sphere spectrophotometer, which can be calculated by a formula “absorptivity (%)=100×{incident light intensity−(reflection light intensity+transmitted light intensity)}/incident light intensity”.

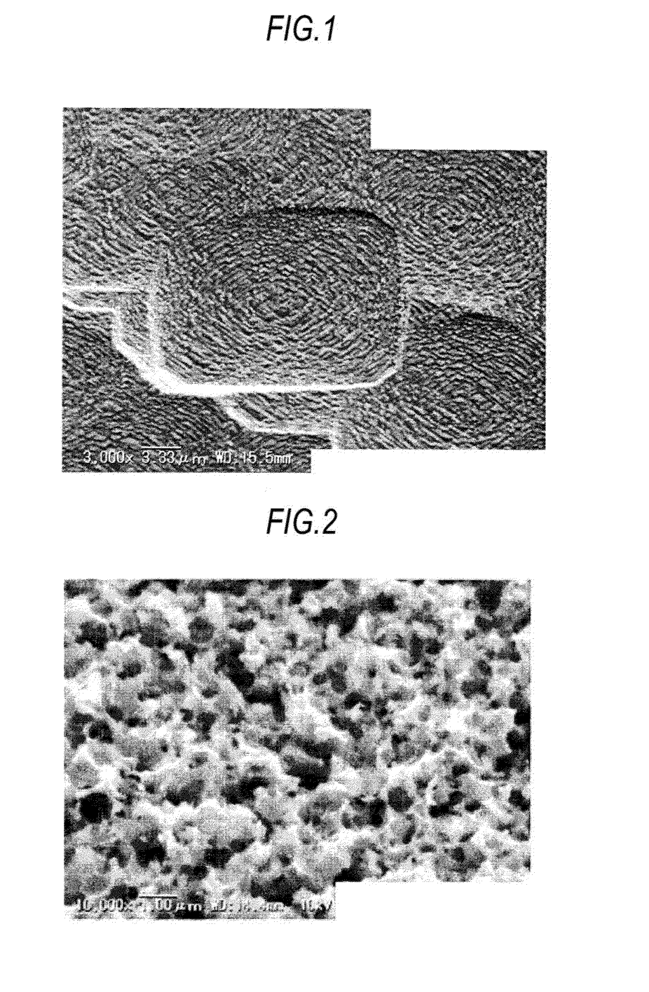

Specifically, the fine uneven surface according to the present invention can be observed as a ripple pattern (refer to FIG. 1), in which the depth of concave portions is normally 10 nm to 200 nm, and preferably 10 nm to 100 nm.

One of features of the silicon substrate having the fine uneven surface according to the present invention is that uneven portions are formed on the opposite side surface of the texture surface and the depth thereof is 10 nm to 200 nm.

A silicon dioxide film or a silicon nitride film is previously formed as a texture etching mask, then, textures are formed by the wet process and the texture mask is removed. When the wet washing is performed, the opposite surface of the textures can be almost planarized.

When the textures are formed by the wet etching process without using the texture etching mask, for example, the height of projections of textures formed by the wet etching method is 10 to 20 μm and the fine uneven surface as in the present invention is not formed on the opposite side of the texture-formed surface.

The finer the structure of the fine uneven surface is, the more the reflection of light on the fine uneven surface is suppressed, and further, when the fine uneven surface is formed on the opposite side, light reflection can be suppressed also on the opposite side to confine light in the silicon substrate. For example, when the processing accuracy of the fine uneven surface is 200 nm or less, reflection of light having a wavelength of 200 nm on the fine uneven surface can be almost 0.

Another feature of the silicon substrate having the fine uneven surface according to the present invention is that the silicon substrate can be reduced in thickness. As the fine uneven surface on the opposite surface of the silicon substrate having textures has the fine uneven structure, light propagating in the substrate can be reflected and can be confined in the substrate even when the thickness of the silicon substrate is reduced, therefore, the substrate can be reduced in thickness.

The thickness of the silicon substrate according to the present invention is 150 μm or less including the depth of the concave portions, preferably 100 μm or less, and further preferably 50 μm or less. The lower limit of the thickness of the silicon substrate is not particularly limited as long as the strength can be maintained as the substrate, and is normally 10 μm or more.

The density of uneven portions in the fine uneven surface is preferably 10 to 1000 pieces per unit area (100 μm²). It is also possible that the fine uneven surface is formed over the entire surface of the silicon substrate or that the fine uneven surface is formed on part of the surface of the silicon substrate.

For example, when the silicon substrate according to the present invention is used as a silicon substrate for a solar cell, it is preferable that the fine uneven surface is not formed on an area where surface electrodes arranged on the light receiving surface side (including a connector electrode, a bar electrode, a grid electrode and so on) are formed, and that the area is planarized.

Another feature of the silicon substrate having the fine uneven surface according to the present invention is that the efficiency of a back junction solar cell is further improved. The back junction solar cell has a structure in which a p-type electrode and an n-type electrode are arranged on the opposite side of the light receiving surface, which can take more light by the area of the wiring width as compared with the related-art solar cell in which electrodes are arranged on the light receiving surface.

When an n-type diffusion region and a p-type diffusion region are formed on the silicon substrate, a wiring process is performed and so on, a photolithography or a printing method are used. Because leakage can occur when the n-type diffusion region and the p-type diffusion region contact each other, which has an adverse effect on characteristics of the solar cell, these regions are arranged so as to leave a space therebetween to avoid the contact. However, when the space is too wide and an exposed portion of the silicon substrate is too large, it can also deteriorate characteristics of the solar cell. Accordingly, it is necessary to leave a space of approximately 10 to 200 μm between the n-type diffusion region and the p-type diffusion region. Moreover, a flat structure is necessary on the wiring side, and light may come off from the substrate.

However, as the fine uneven surface is formed on the wiring side of the silicon substrate according to the present invention so as to maintain the processing accuracy of wiring, light can be reflected also on the backside of the silicon substrate. As a result, the efficiency of the back-contact structure solar cell can be further improved.

2. A manufacturing method of the silicon substrate having the fine uneven surface:

A feature of the manufacturing method of the silicon substrate according to the present invention is a point that the silicon substrate is processed by non-plasma. Under this condition, a step of preparing a silicon substrate having a substrate plane orientation (100) with textures and a step of spraying an etching gas to the silicon substrate are included. Preferably, a step of spraying a cooling gas to the silicon substrate is further included, and the step of spraying the etching gas and the step of spraying the cooling gas may be alternately repeated.

The silicon substrate having the substrate plane orientation (100) is a single-crystal silicon substrate in which an orientation of a principal plane is the (100) plane. The silicon substrate may be a semiconductor wafer or a semiconductor layer stacked on another substrate. In any case, the fine uneven surface is formed on the backside of the substrate on which textures are formed on the (100) plane as the orientation of the principal plane.

The silicon substrate to be prepared may use intrinsic silicon as well as p-fype or n-type doped silicon. When the silicon substrate for the solar cell is obtained, a p-type doped silicon substrate is prepared in many cases.

The spraying of the etching gas to the silicon substrate is preferably performed under a reduced pressure condition of atmospheric pressure to 80 KPa. The pressure is preferably 30 KPa or less, more preferably 20 KPa or less, and further preferably 10 KPa or less, or may be 50 KPa or less. When the etching is performed under a lower pressure condition, a more precise shape can be obtained. On the other hand, when the etching is performed under a higher pressure, a finer shape can be obtained.

The etching gas includes at least one of ClF₃, XeF₂, BrF₃, BrF₅ and NF₃ (also referred to as a fluorine containing gas). The fluorine containing gas included in the etching gas can be a mixed gas including two or more kinds of these gases.

Moreover, the etching gas preferably includes a gas containing oxygen atoms in molecules thereof in addition to the fluorine containing gas. The gas containing oxygen atoms is typically oxygen gas (O₂), and may be carbon dioxide (CO₂) or nitrogen dioxide (NO₂).

Molecules of the fluorine containing gas are physically adsorbed on the surface of the silicon substrate and moved to an etching site. The gas molecules which nave reached the etching site are decomposed and react with silicon to form a volatile fluorine compound. Accordingly, a silicon surface on the opposite side of the surface on which textures are formed is etched to form the fine uneven surface.

It is preferable that the etching gas further includes an inert gas in addition to the fluorine containing gas. The inert gas includes nitrogen gas, argon, helium and so on, which may be a gas not having reactivity with silicon. The inert gas included in the etching gas may be a mixed gas including two or more kinds of these gases.

The total concentration (volume concentration) of the inert gas in the etching gas is preferably three times or more as high as the total concentration of the fluorine containing gas, and may be 10 times or 20 times or more. The higher the total concentration of the fluorine containing gas in the etching gas is, the larger the uneven portions tend to be (the larger the depth of concave portions tends to be). Accordingly, when the concave portions are desired to be small, the concentration of the inert gas is increased to thereby relatively reduce the concentration of the fluorine containing gas.

When the concentration of the inert gas in the etching gas is low and the concentration of the fluorine containing gas is relatively increased, the surface of the silicon substrate may easily be etched in an isotropic manner, therefore, it may be difficult to form the desired fine uneven surface on the surface of the silicon substrate.

The concentration (volume concentration) of the fluorine containing gas in the etching gas is preferably 1% to 10%, and more preferably 2% to 5%. The concentration (volume concentration) of the oxygen-atom containing gas in the etching gas is preferably 4 to 40% with respect to the total concentration of the fluorine containing gas and the inert gas. The concentration (volume concentration) of the oxygen-atom containing gas in the etching gas is preferably three times to 10 times as high as the total concentration of the fluorine containing gas. When the concentration of the oxygen-atom containing gas in the etching gas is too low, it may be difficult to obtain the desired fine uneven surface due to overetching.

The fine uneven surface for further improving the performance of the solar cell can be formed on the surface of the semiconductor substrate by allowing the etching gas to include the oxygen-atom containing gas. Though the reason is not particularly limited, for example, when the ClF₃ gas is physically adsorbed on the silicon surface, the ClF₃ reacts with silicon to form a SiF₃ gas. At this time, oxygen atoms terminate dangling bonds of a silicon network structure, thereby partially forming a Si—O coupling. Accordingly, a region where etching is easy (Si—Si.) and a region where etching is not easy (Si—O) are formed. It is conceivable that the chemical reaction is promoted due to the difference in the etching rate.

When the pressure of spraying the etching gas to the substrate surface is increased, the surface of the fine uneven surface to be obtained may be formed in a staircase pattern or in a multilayer state. In order to increase the spraying pressure, for example, a gap between the substrate surface and a nozzle of the etching gas may be narrowed or the flow rate of the etching gas to be sprayed may be increased.

In a manufacturing method of the silicon substrate according to the present invention, it is important to maintain the temperature of the silicon substrate to be low during etching. The temperature of the silicon substrate is preferably 50° C. to 150° C. Moreover, the temperature is preferably maintained at 130° C. or less, more preferably maintained at 100° C. or less, and furthermore preferably maintained at 80° C. or less. In order to maintain the temperature of the silicon substrate to be low, it is preferable that the temperature of a stage on which the silicon substrate is placed is maintained at approximately room temperature (25° C).

As described above, the manufacturing method of the silicon substrate according to the present invention may include the step of spraying the cooling gas to the silicon substrate. The cooling gas is the same as the above inert gas, including nitrogen gas, argon, helium and so on. The cooling gas is sprayed to the silicon substrate which has been heated by the reaction with the etching gas, thereby cooling the heated substrate.

In the manufacturing method of the silicon substrate according to the present invention, the step of spraying the etching gas and the step of spraying the cooling gas to the silicon substrate may be alternately repeated. The substrate temperature can be maintained to be low by controlling a process time in the step of spraying the etching gas to the silicon substrate. The process time is not particularly limited and may be approximately 1 to 10 minutes. After the step of spraying the etching gas to the silicon substrate, the cooling gas is sprayed to thereby reduce the substrate temperature, and then, the etching gas may be sprayed to the silicon substrate again.

After the fine uneven surface is formed on the surface of the silicon substrate by the etching gas, it is preferable to remove the etching gets or decomposition thereof remaining on the silicon substrate. For example, the residual fluorine compound may be removed by placing the silicon substrate in a hydrogen gas atmosphere.

It is also possible to form a silicon substrate in which oxide films on silicon surfaces (the texture surface and the fine uneven surface) are etched and the surface of which has been further activated by washing by a fluonitric acid solution the silicon substrate on which the fine uneven surface is formed on the opposite surface of the surface on which textures are formed. As a washing liquid, an alkaline solution can be used, and for example, sodium hydroxide can be used.

3. Applications of the silicon substrate having the surface on which textures are formed and the surface on which fine rectangular-shaped unevenness is formed in the ripple shape:

The silicon substrate according to the present invention is preferably used as a silicon substrate for a solar cell. In order to form the silicon substrate for the solar cell, it is preferable to form an emitter layer and a pn junction on the texture-formed surface of the silicon substrate.

For example, when the texture-formed surface is formed on a p-type silicon substrate, an n-type emitter layer is formed on the texture-formed surface by heating the texture-formed surface in a pbosphorus-oxychloride gas atmosphere to form the pn junction. Moreover, an antireflection layer may be stacked on the emitter layer, thereby farther reducing the reflection as the solar cell and improving the photoelectric conversion ratio. The antireflection layer may be a silicon nitride film, silicon oxide film, a titanium oxide film or the like.

Furthermore, surface electrodes may be arranged on the texture-formed surface as the light receiving surface and backside electrodes may be arranged on the fine uneven surface as the non-light receiving surface to thereby form the solar cell. Naturally, the example of the solar cell is not limited to the above.

### EXAMPLES

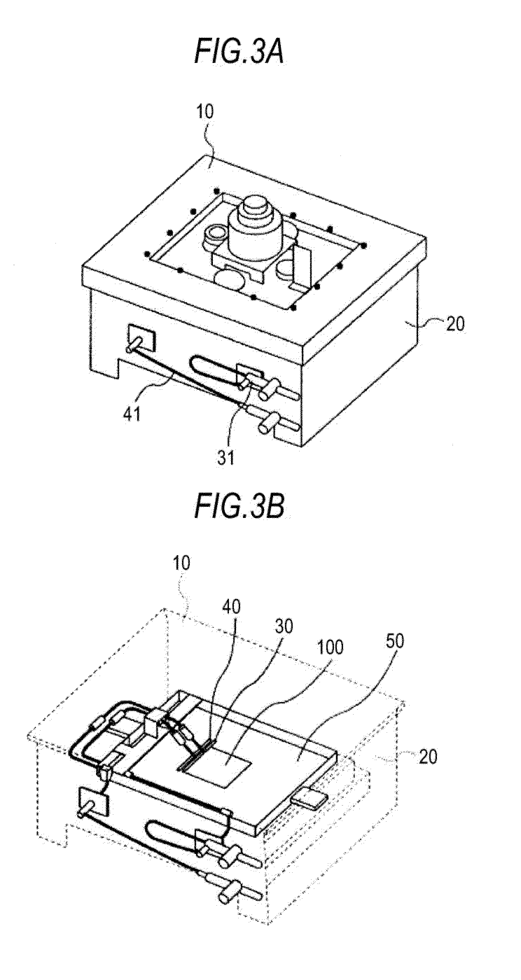

FIGS. 3A and 3B show an outline of a device for forming the fine uneven surface used in the example.

FIG. 3A is an external perspective view of a device for forming the fine uneven surface 10. FIG. 3B is a perspective view when seeing through the inside of a reduced pressure chamber 20. The device for forming the fine uneven surface 10 shown in FIGS. 3A and 3B has a nozzle 30 for spraying the etching gas, a nozzle 40 for spraying the cooling gas and a stage 50 for placing a silicon substrate 100 thereon in the reduced pressure chamber 20.

The nozzle 30 is connected to an etching gas supply piping 31 and the nozzle 40 is connected to a cooling gas supply piping 41. The etching gas and the cooling gas are sprayed to the silicon substrate 100 placed on the stage 50 to thereby manufacture the silicon substrate having the fine-unevenness formed surface.

### Example 1

The silicon substrate 100 having the substrate plane orientation (100) on which textures were formed was placed on the stage 50 of the device for forming the fine uneven surface 10 shown in FIG. 3B.

A gap between the nozzle 30 and the silicon substrate 100 was set to 10 mm. The area of the substrate surface of the silicon substrate 100 having the substrate plane orientation (100) on which textures are formed is 125 mm×125 mm. The temperature of the stage 50 was set to 25° C. After the pressure inside the reduced pressure chamber 20 was adjusted to 90 KPa, the etching gas from the nozzle 30 was sprayed for three minutes to the surface opposite to textures of the silicon substrate 100 having the substrate plane orientation (100) on which textures were formed.

The composition of the sprayed etching gas was “ClF₃/O₂/N₂=50 to 1000cc/3500cc/1000 to 5000 cc”. Next, the silicon substrate to which the etching gas was sprayed was dipped in a fluonitric acid solution for five minutes.

The obtained fine-unevenness formed surface of the silicon substrate is shown in FIG. 1. As shown in FIG. 1, it is found that the depth of the concave portions is 10 nm to 200 nm.

### Comparative Example 1

The silicon substrate 100 having the substrate plane orientation (100) on which textures were formed was placed on the stage 50 of the device for forming the fine uneven surface 10 shown in FIG. 3B.

The area of the substrate surface of the silicon substrate 100 having the substrate plane orientation (100) on which textures are formed is 125 mm×125 mm. The temperature of the stage 50 was set to 80° C. After the pressure inside the reduced pressure chamber 20 was adjusted to 90 KPa, the etching gas from the nozzle 30 was sprayed for three minutes to the surface opposite to textures of the silicon substrate 100 having the substrate plane orientation (100) on which textures were formed. The composition of the sprayed etching gas was “ClF₃/O₂/N₂=500 cc/0 cc/2000 to 5000 cc”.

The shape of the obtained opposite surface of the silicon surface having the substrate plane orientation (100) on which textures are formed is shown in FIG. 2. As shown in FIG. 2, though the surface of the silicon substrate was roughened, the shape was irregular and the fine uneven surface was not formed. It is assumed that this is because the temperature of the silicon substrate has not been maintained in a low temperature.

The reflectance and absorptivity of the substrate having the fine uneven surface on the opposite surface of the silicon substrate with textures obtained by Example 1 were measured. Moreover, the reflectance and absorptivity of the substrate on which the fine uneven surface is not formed on the opposite surface of the silicon substrate having the substrate plane orientation (100) on which textures were formed were measured as the reference example. The measurement of the reflectance and absorptivity was performed by an integrating sphere spectrophotometer (U4000 manufactured by Hitachi High-Tech Fielding Corporation).

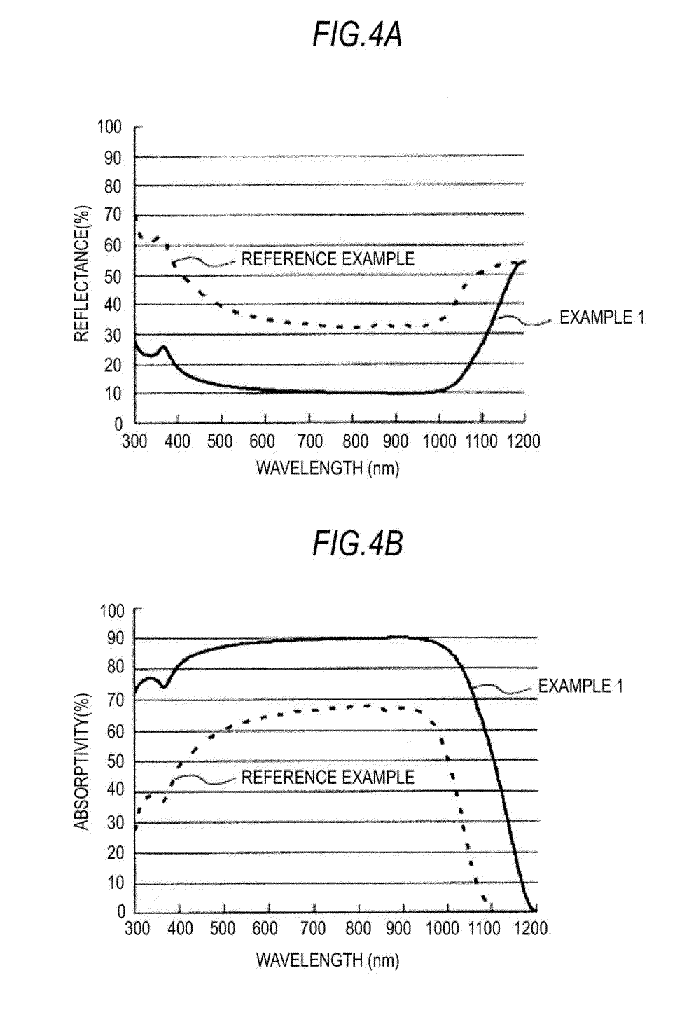

FIG. 4A is a graph showing the reflectance in the substrate (reference example) on which the fine uneven surface is not formed on the opposite surface of the silicon substrate with the substrate plane orientation (100) on which textures are formed, and in the substrate having the fine uneven surface on the opposite surface of the silicon substrate having textures obtained in Example 1. FIG. 4B is a graph showing the absorptivity in the substrate (reference example) on which the fine uneven surface is not formed on the opposite surface of the silicon substrate with the substrate plane orientation (100) on which textures are formed, and in the substrate having the fine uneven surface on the opposite surface of the silicon substrate having textures obtained in Example 1.

As shown in FIGS. 4A and 4B, the reflectance (wavelength 500 nm to 1000 nm) of the substrate having the fine uneven surface on the opposite surface of the silicon substrate having textures in Example 1 is suppressed to 20% or less as well as the absoptivity (wavelength 500 nm to 1000 nm) thereof is increased to 80% or more.

The silicon substrate according to the present invention has the fine uneven surface on the opposite surface of the silicon substrate having textures, and the reflectance thereof is low. Additionally, the silicon substrate having the fine uneven surface on the opposite surface of the silicon substrate having textures has higher light-confinement efficiency than related-art substrates. Accordingly, the substrate having the fine uneven surface on the opposite surface of the silicon substrate having textures can be suitably used for the silicon substrate for the solar cell, which contributes to improvement of the photoelectric conversion ratio of the solar cell.

What is claimed is:

1. A silicon substrate having a substrate plane orientation (100), comprising:
textures on one surface for receiving light; and
fine rectangular-shaped uneven portions in a ripple shape on another surface opposite to the one surface on which the textures are formed,
wherein the depth of concave portions in the uneven portions is 10 to 200 nm.

2. The silicon substrate according to claim 1,
wherein the depth of each of the unevenness formed in the ripple shape ranges from 10 nm to 100 nm.

3. The silicon substrate according to claim 1,
wherein the density of the unevenness on the another surface is 10 to 100000 pieces/100 μm².

4. The silicon substrate according to claim 1,
wherein the absorptivity of incident light (wavelength 0.5 to 10 μm) onto the silicon substrate is 80% or more.

5. A manufacturing method of a silicon substrate comprising:
preparing a silicon substrate having a substrate plane orientation (100); and
spraying an etching gas to the surface of the silicon substrate,
wherein the etching gas includes one or sore gases selected from the group consisting of ClF₃, XeF₂, BrF₃, BrF₅ and NF₃ as well as a gas containing oxygen atoms in molecules,
the concentration of the gases selected from ClF₃, XeF₂, BrF₃, BrF₅ and NF₃ with respect to the total flow rate during etching processing is 1 to 10%, and
the surface of the silicon substrate is processed by non-plasma.

6. The manufacturing method of the silicon substrate according to claim 5,
wherein the etching gas further includes an inert gas.

7. The manufacturing method of the silicon substrate according to claim 5,
wherein, in the etching gas, the concentration of the gas containing oxygen atoms in molecules with respect to the total flow rate during etching processing is 4 to 40%.

8. The manufacturing method of the silicon substrate according to claim 5,
wherein, in the etching gas, the ratio between the one or more gases selected from the group consisting of ClF₃, XeF₂, BrF₃, BrF₅ and NF₃ and the gas containing oxygen atoms in molecules is 1:10 to 1:3.

9. The manufacturing method of the silicon substrate according to claim 5,
wherein the temperature of the silicon substrate is maintained to 130° C. or less.

10. The manufacturing method of the silicon substrate according to claim 5,
wherein the etching processing of the silicon substrate is performed under a reduced pressure condition.

11. The manufacturing method of the silicon substrate according to claim 5, further comprising:
washing the silicon substrate,
wherein the washing of the silicon substrate is performed by using flue-nitric acid.

12. The manufacturing method of the silicon substrate according to claim 5, further comprising:
washing the silicon substrate,
wherein the washing of the silicon substrate is performed by using sodium hydroxide.

13. The manufacturing method of the silicon substrate according to claim 6,
wherein, in the etching gas, the concentration of the gas containing oxygen atoms in molecules with respect to the total flow rate during etching processing is 4 to 40%.

14. The manufacturing method of the silicon substrate according to claim 13,
wherein, in the etching gas, the ratio between the one or more gases selected from the group consisting of ClF₃, XeF₂, BrF₃, BrF₅ and NF₃ and the gas containing oxygen atoms in molecules is 1:10 to 1:3.

15. The manufacturing method of the silicon substrate according to claim 14,
wherein the temperature of the silicon substrate is maintained to 130° C. or less.

16. The manufacturing method of the silicon substrate according to claim 15, further comprising:
washing the silicon substrate,
wherein the washing of the silicon substrate is performed by using fluonitric acid.

17. The manufacturing method of the silicon substrate according to claim 15, further comprising:
washing the silicon substrate,
wherein the washing of the silicon substrate is performed by using sodium hydroxide.

18. The silicon substrate according to claim 2,
wherein the density of the unevenness on the other surface is 10 to 100000 pieces/100 μm².

19. The silicon substrate according to claim 2,
wherein the absorptivity of incident light (wavelength 0.5 to 10 μm) onto the silicon substrate is 80% or more.

20. The silicon substrate according to claim 18,
wherein the absorptivity of incident light (wavelength 0.5 to 10 μm) onto the silicon substrate is 80% or more.
